(19) United States
(12) Patent Application Publication
(10) Pub. No.: US 2021/0341898 A1
(43) Pub. Date: Nov. 4, 2021

(54) DEVICE AND METHOD FOR REAL-TIME MONITORING AND CORRECTING DISPLACEMENT OF INDOOR MICROFORM MODEL MEASURING EQUIPMENT

(71) Applicants: Beixiao Shi, Nanjing (CN); Saichao Liu, Nanjing (CN); Xinlei Wu, Nanjing (CN); Weikun Chang, Nanjing (CN); Weiwei Xu, Nanjing (CN); Guangze Shen, Nanjing (CN); Xiaofeng Han, Nanjing (CN)

(72) Inventors: Beixiao Shi, Nanjing (CN); Saichao Liu, Nanjing (CN); Xinlei Wu, Nanjing (CN); Weikun Chang, Nanjing (CN); Weiwei Xu, Nanjing (CN); Guangze Shen, Nanjing (CN); Xiaofeng Han, Nanjing (CN)

(21) Appl. No.: 17/149,744

(22) Filed: Jan. 15, 2021

(30) Foreign Application Priority Data
Apr. 30, 2020 (CN) 202010362686.4

(51) Int. Cl. G05B 19/05; G06F 30/13; E04B 7/02

(52) U.S. Cl. CPC G05B 19/058; E04B 7/024; G06F 30/13; G05B 19/054

(57) ABSTRACT

The invention discloses a device for real-time monitoring and correcting the displacement of indoor microform model measuring equipment, comprising a measuring equipment, a sensing device, and a adjusting device that are installed on a truss; the outside of the truss is provided with a horizontal and a vertical base point; the sensing device and the adjusting device both take the horizontal and vertical base points as benchmarks, and are both connected to a controller; the adjusting device is connected to the measuring equipment, which can drive the measuring equipment to fine-tune on the truss. The invention further discloses a real-time monitoring and correcting method using the device. The invention is simple in structure, convenient to use, and easy to install. Since an automatic adjusting device is used, the adjustment value can be accurate to 0.01 mm, making the data obtained from the indoor model observation test more accurate and reliable.

### BACKGROUND OF THE INVENTION

### 1. Field of the Invention

The invention relates to an automatic displacement adjusting device in the field of experimental technology development, in particular to a device and method for real-time monitoring and correcting the displacement of indoor microform model measuring equipment.

### 2. Description of the Related Art

The indoor large-scale physical model test is generally an indoor miniature model made according to the needs of the project, which is smaller than the actual size of the project. Through the indoor miniature model test to accurately reflect the project, it is necessary to accurately measure the fine movement trajectory and displacement changes of the indoor model. Therefore, it is often necessary to set up measurement equipment in the air. Based on a 1:150 scale indoor miniature model of a large lake, the observation equipment is suspended on the vertical truss of the model hall to observe the movement parameters of the lake surface such as waves and sediment. When changes in the external environment (such as temperature, wind, etc.) cause a 1 mm displacement in the vertical direction of the measuring equipment, it is equivalent to the actual lake level rising or falling by 150 mm, and for the entire lake's storage capacity, it is equivalent to an increase or decrease of nearly 100,000 m³, which leads to distortion of the test results. At present, there is no device for real-time monitoring and correction of the trace displacement of the measuring equipment of the indoor large-scale physical model test.

### SUMMARY OF THE INVENTION

The purpose of the invention is to solve the problem of horizontal or vertical displacement of the measuring equipment installed on the truss due to changes in external factors such as air temperature or wind, which in turn leads to distortion of the test results, and to provide a device and method for real-time monitoring and correcting the displacement of indoor microform model measuring equipment, which can automatically monitor and correct the measurement equipment, with a simple structure and strong practicability, and is convenient for installation by testers.

In order to achieve the above purpose, the invention adopts the following technical solutions:

a device for real-time monitoring and correcting the displacement of indoor microform model measuring equipment, comprising a measuring equipment, a sensing device, and a adjusting device that are installed on a truss, wherein the outside of the truss is provided with a horizontal base point and a vertical base point; the sensing device and the adjusting device both take the horizontal base point and the vertical base point as benchmarks, and the sensing device and the adjusting device are both connected to a controller through a data line; the adjusting device is connected to the measuring equipment, which can drive the measuring equipment to fine-tune on the truss.

The top view projections of the horizontal base point, the vertical base point, the adjusting device and the sensing device are in the same Cartesian two-dimensional coordinate system; the center point and the horizontal base point of the adjusting device and the sensing device are on the X axis, with the center of the sensing device as the circle point; the coordinates of the horizontal base point are (L4, 0), and the coordinates of the vertical base point are (0, L0).

The truss is a frame structure, and the top center is vertically connected with a vertical truss downward.

The measuring equipment and the sensing device are both installed on the vertical truss.

The adjusting device comprises a steel square frame fixedly installed at the bottom of the vertical truss; the upper part of the two adjacent bottom edges of the square frame are respectively provided with guide rails arranged along the length thereof, and each bottom edge is provided with an electric push rod whose bottom is clamped on the guide rail; the two electric push rods are arranged in a cross, and the end shaft heads of the two electric push rods are fixedly connected to a collar; the collar is sleeved on an upwardly extending casing of the measuring equipment, and there is a gap between the collar and the casing, which can ensure that the measuring equipment can move up and down freely; each electric push rod is equipped with an electromagnetic chuck in contact with the bottom edge; the electromagnetic chuck fixes the electric push rod on the bottom edge when it is energized; when the electric push rod is required to slide on the bottom edge, the electromagnetic chuck is deenergized;

one of the electric push rods is equipped with a micro stepping motor that has an angle with the push rod on the shaft head closed to the end; the end of the output shaft of the micro stepping motor is equipped with a gear; the casing is provided with a rack meshed with the gear; when the micro stepping motor works, the gear rotates, and the casing and the measuring equipment move up and down through the action of the rack meshed with the gear.

The electric push rod, the electromagnetic chuck and the micro stepping motor are all controlled by the controller.

The sensing device is a laser displacement sensor.

The controller is a PLC or a single-chip microcomputer or a computer.

The electric push rod is a new type of electric actuator. The electric push rod is mainly composed of a motor, a push rod and a control device, which can realize remote control and centralized control.

A real-time monitoring and correcting method using the device for real-time monitoring and correcting the displacement of indoor microform model measuring equipment, comprising the following steps:

1) selecting a horizontal base point and a vertical base point with the same position; the top view projections of the horizontal base point, the vertical base point, the adjusting device and the sensing device are in the same Cartesian two-dimensional coordinate system; the center point and the horizontal base point of the adjusting device and the sensing device are on the X axis, with the center of the sensing device as the circle point; the coordinates of the horizontal base point are (L4, 0), and the coordinates of the vertical base point are (0, L0);

2) fixing the sensing device, the adjusting device and the measuring equipment on the vertical truss;

3) the sensing device measures its distance from the horizontal base point and the vertical base point by emitting a laser beam to the horizontal base point and the vertical base point;

4) setting the distance between the measuring equipment and the horizontal base point and the vertical base point unchanged, and the error is less than 0.01 mm;

5) automatic adjustment; if the measuring equipment has a displacement greater than or equal to 0.01 mm due to changes in the external environment, the sensing device will sense in real time and convert the displacement signal into an electrical signal and transmit it to the controller, and the controller controls the adjusting device to make corresponding adjustments to restore the measuring equipment to the standard position.

In the invention, the measuring equipment is an existing equipment, which can be purchased in the market, and will not be repeated.

The advantageous effects of the invention are:

The invention can reduce the influence of changes in the external environment on the observation test of a large physical model, such as temperature and wind that cause the position of the measuring equipment to change, and the problems of inaccurate data obtained by observation. Select the horizontal and vertical base points on the ground, fix the sensing device on the vertical truss, and fix the adjusting device at a distance L0 from the vertical base point; when the change of the external environment causes the position of the measuring equipment to change, the sensing device senses the change in its displacement, and transmits the displacement signal to the controller in real time, and the controller controls the adjusting device to make adjustments. The principle is to set the distance between the measuring equipment and the horizontal and vertical base point unchanged, and the sensing device emits a laser beam to sense its position change; when the displacement change of the measuring equipment is greater than or equal to 0.01 mm, the sensing device senses the displacement change and transmits the displacement signal to the controller in real time, and the controller controls the adjusting device to make adjustments.

The invention is simple in structure, convenient to use, and easy to install. Since an automatic adjusting device is used instead of manually measuring the displacement and manually adjusting, so the adjustment value can be accurate to 0.01 mm, which makes the data obtained from the indoor model observation test more accurate and reliable, makes the observation error between the indoor miniature model and the actual model smaller, and is of great significance for the observation of indoor large-scale physical model experiments.

### BRIEF DESCRIPTION OF THE DRAWINGS

FIG. 1 is a schematic diagram of the overall device system;

FIG. 2 is a schematic top view of the overall device;

FIG. 3 is a schematic diagram of the structure of the measuring equipment;

FIG. 4 is a schematic diagram of the connection of the vertical truss, the adjusting device and the measuring equipment;

FIG. 5 is a schematic diagram of the structure of the adjusting device;

FIG. 6 is a schematic diagram of the structure of the sensing device.

In the figures, 1 refers to the measuring equipment; 2 refers to the adjusting device; 3 refers to the downward L0-L1 displacement of the sensing device; 4 refers to the sensing device; 5 refers to the upward L2-L0 displacement of the sensing device; 6 refers to the downward deformation of the truss; 7 refers to the upward deformation of the truss; 8 refers to the building truss; 9 refers to the vertical base point; 10 refers to the model; 11 refers to the vertical truss; 12 refers to the horizontal base point; 13 refers to the monitoring camera; 14 refers to the protective tube; 15 refers to the monitoring wiring; 16 refers to the rack; 17 refers to the square frame; 18 refers to the casing; 19 refers to the bolt; 20 refers to the operation panel; 21 refers to the sensor; 22 refers to the wire; 23 refers to the laser receiving window; 24 refers to the laser emitting window; 25 refers to the laser displacement sensor; 26 refers to the electromagnetic chuck; 27 refers to the micro stepping motor; 28 refers to the gear; 29 refers to the collar; 30 refers to the guide rail; 31 refers to the bottom edge; 32 refers to the electric push rod.

### DETAILED DESCRIPTION OF THE PREFERRED EMBODIMENTS

The invention will be further described in detail hereinafter with reference to the drawings and embodiments.

The structure, ratio, size, etc. shown in the drawings in this manual are only used to match the content disclosed in the manual for the understanding and reading of those familiar with this technology, but not to limit the conditions under which the invention can be implemented, so it has no technical significance. Any structural modification, proportional relationship change or size adjustment should still fall within the scope of the technical content disclosed in the invention, without affecting the effects and objectives that the invention can produce. At the same time, terms such as “upper”, “lower”, “left”, “right”, “middle” and “one” quoted in the specification are only for ease of description, but not to limit the implementable scope of the invention, and the change or adjustment of the relative relationship should be regarded as the implementable scope of the invention without substantially changing the technical content.

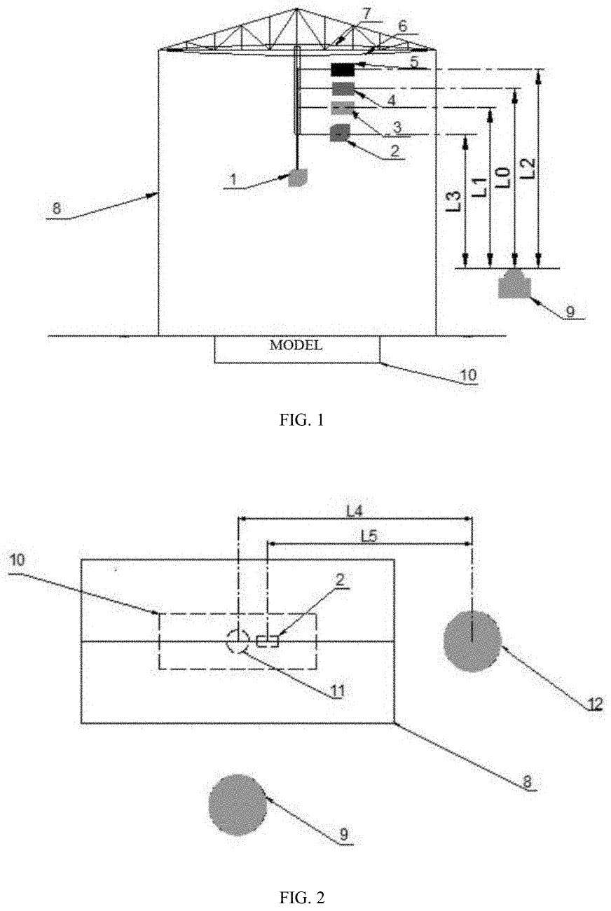

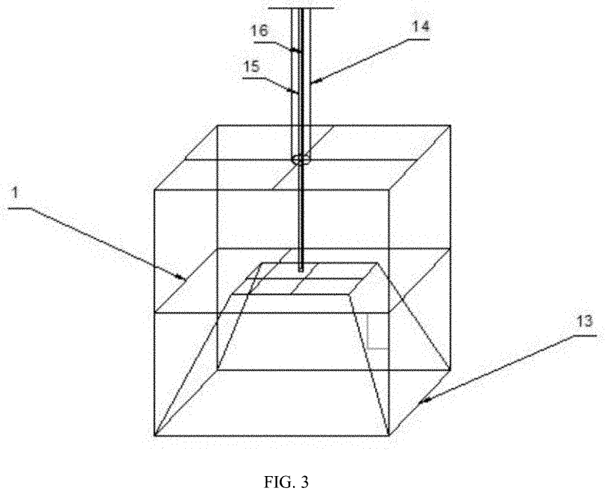

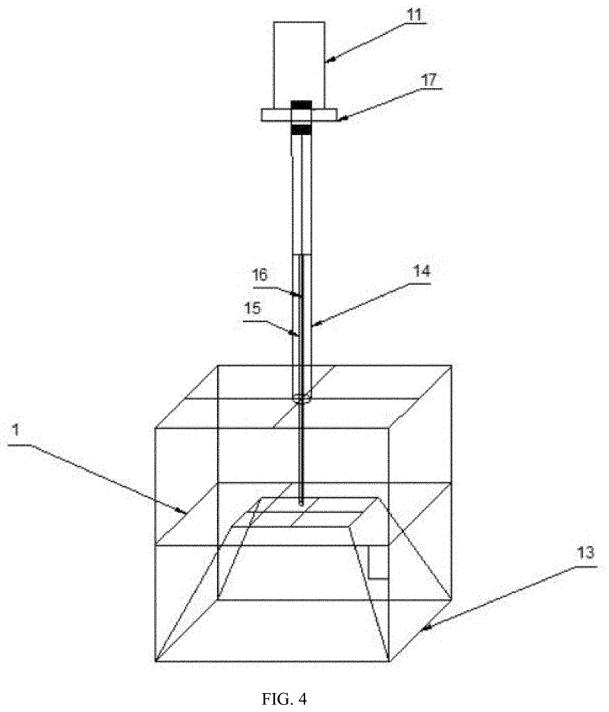

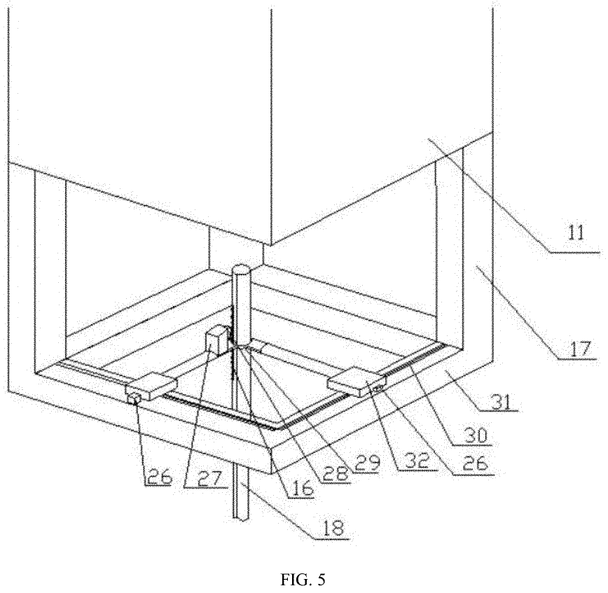

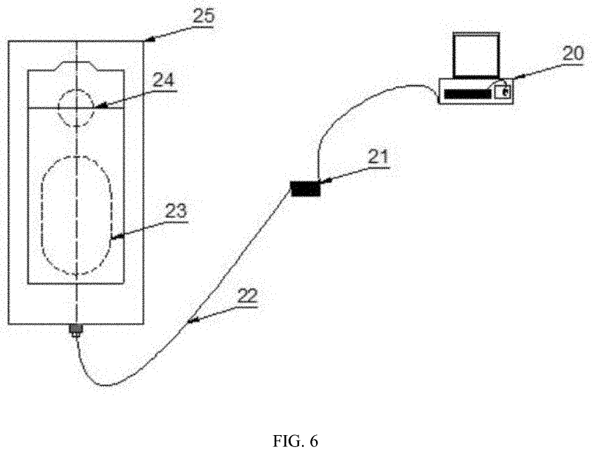

With reference to FIG. 1-6, a device for real-time monitoring and correcting the displacement of indoor microform model measuring equipment, comprising a measuring equipment 1, a adjusting device 2, a sensing device 4, a vertical base point 9, a building truss 8, a model 10, a horizontal base point 12, and a vertical truss 11; the building truss 8 is a frame structure, and the top center is vertically connected with a vertical truss 11 downward. The measuring equipment 1, the sensing device 4 and the adjusting device 2 are all fixed on the vertical truss 11 of the building truss 8; the outside of the building truss 8 is provided with a horizontal base point 12 and a vertical base point 9; the sensing device 4 and the adjusting device 2 both take the horizontal base 12 point and the vertical base point 9 as benchmarks, and the sensing device 4 and the adjusting device 2 are both connected to a controller through a data line; the adjusting device 2 is connected to the measuring equipment 1, which can drive the measuring equipment 1 to fine-tune on the truss. The sensing device 4 is a laser displacement sensor, such as a BX-LV100N/R laser displacement sensor. The controller is a PLC or a single-chip microcomputer or a computer.

The top view projections of the horizontal base point 12, the vertical base point 9, the adjusting device 2 and the sensing device 4 are in the same Cartesian two-dimensional coordinate system; the center point and the horizontal base point 12 of the adjusting device 2 and the sensing device 4 are on the X axis, with the center of the sensing device 4 as the circle point; the coordinates of the horizontal base point 12 are (L4, 0), and the coordinates of the vertical base point 9 are (0, L0).

As shown in FIG. 5, the adjusting device 2 comprises a steel square frame 17 fixedly installed at the bottom of the vertical truss 11; the upper part of the two adjacent bottom edges 31 of the square frame 17 are respectively provided with guide rails 30 arranged along the length thereof, and each bottom edge 31 is provided with an electric push rod 32 whose bottom is clamped on the guide rail 30; the two electric push rods 32 are arranged in a cross, and the end shaft heads of the two electric push rods 32 are fixedly connected to a collar 29; the collar 29 is sleeved on an upwardly extending casing 18 of the measuring equipment 1, and there is a gap between the collar 29 and the casing 18, which can ensure that the measuring equipment 1 can move up and down freely; each electric push rod 32 is equipped with an electromagnetic chuck 26 in contact with the bottom edge 31; the electromagnetic chuck 26 fixes the electric push rod 32 on the bottom edge 31 when it is energized; when the electric push rod 32 is required to slide on the bottom edge 31, the electromagnetic chuck 26 is deenergized;

one of the electric push rods 32 is equipped with a micro stepping motor 27 that has an angle with the push rod on the shaft head closed to the end; the end of the output shaft of the micro stepping motor 27 is equipped with a gear 28; the casing 18 is provided with a rack 16 meshed with the gear 28; when the micro stepping motor 27 works, the gear 28 rotates, and the casing 18 and the measuring equipment 1 move up and down through the action of the rack 16 meshed with the gear 28. The electric push rod 32, the electromagnetic chuck 26 and the micro stepping motor 27 are all controlled by the controller.

The electric push rod is a new type of electric actuator. The electric push rod is mainly composed of a motor, a push rod and a control device, which can realize remote control and centralized control.

The measuring equipment, the electric push rod and the micro stepping motor are all existing products, which can be purchased in the market, and will not be repeated.

The working principle and process of the invention:

When in use, the sensing device 4 automatically senses the distance between the measuring equipment 1 and the vertical base point 9 and the horizontal base point 12; setting the distance to the horizontal base point and the vertical base point unchanged; when the external environment changes (such as temperature, wind, etc.), as shown in FIG. 1, the truss is deformed downward 6 or the truss is deformed upward 7, which causes the sensing device to make the downward L0-L1 displacement 3, or the sensing device to make the upward L2-L0 displacement 5, and causes the measuring equipment to produce synchronous displacement, so the measurement is inaccurate. When the horizontal or vertical displacement of the measuring equipment 1 is set to be greater than 0.01 mm, the sensing device 4 converts the displacement signal into an electrical signal and transmits it to the controller, and the controller controls the adjusting device to make corresponding adjustments so that the deviation of the horizontal and vertical displacement of the measuring equipment 1 does not exceed 0.01 mm.

A real-time monitoring and correcting method using the device for real-time monitoring and correcting the displacement of indoor microform model measuring equipment, comprising the following steps:

1) selecting a horizontal base point and a vertical base point;

2) fixing the sensing device, the adjusting device and the measuring equipment on the vertical truss;

3) the sensing device measures its distance from the horizontal base point and the vertical base point by emitting a laser beam to the horizontal base point and the vertical base point;

4) setting the distance between the measuring equipment and the horizontal base point and the vertical base point unchanged, and the error is less than 0.01 mm;

5) automatic adjustment; if the measuring equipment has a displacement greater than or equal to 0.01 mm due to changes in the external environment, the sensing device will sense in real time and convert the displacement signal into an electrical signal and transmit it to the controller, and the controller controls the adjusting device to make corresponding adjustments to restore the measuring equipment to the standard position.

The specific adjustment method is:

up and down movement: the electromagnetic chuck 26 is energized, the electric push rod 32 is fixed on the square frame 17 to control the action of the micro stepping motor 27, and the casing 18 of the measuring equipment 1 is driven up and down through the collar 29 by the engagement of the gear and the rack.

Left and right movement: deenergizing the electromagnetic chuck 26 of the electric push rod 32 to facilitate the electric push rod 32 to slide on the guide rail; the electric push rod moving forward and backward is deenergized, the electric push rod 32 moving left and right is energized, and act according to the requirements of the controller, which drives the collar 29 and the casing 18 inside to move left and right; the electric push rod moving forward and backward slides synchronously on the guide rail 30.

Forward and backward movement: deenergizing the electromagnetic chuck 26 of the electric push rod 32 to facilitate the electric push rod 32 to slide on the guide rail; the electric push rod moving left and right is deenergized, the electric push rod 32 moving forward and backward is energized, and act according to the requirements of the controller, which drives the collar 29 and the casing 18 inside to move forward and backward; the electric push rod moving left and right slides synchronously on the guide rail 30.

After the front, back, left, and right adjustments are in place, the electric push rod 32 is deenergized, and the electromagnetic chuck 26 is energized; the electric push rod 32 is fixed on the square frame 17 to prevent the electric push rod from moving to affect the accuracy of the measurement equipment.

Although the specific embodiments of the invention have been described hereinabove with reference to the drawings, they are not intended to limit the protection scope of the invention. Those skilled in the art should understand that on the basis of the technical solution of the invention, various modifications or variations may be made by those skilled in the art without creative efforts, which shall all fall within the protection scope of the invention.

1. A device for real-time monitoring and correcting the displacement of indoor microform model measuring equipment, comprising a measuring equipment, a sensing device, and a adjusting device that are installed on a truss, wherein the outside of the truss is provided with a horizontal base point and a vertical base point; the sensing device and the adjusting device both take the horizontal base point and the vertical base point as benchmarks, and the sensing device and the adjusting device are both connected to a controller through a data line; the adjusting device is connected to the measuring equipment, which can drive the measuring equipment to fine-tune on the truss.

2. The device for real-time monitoring and correcting the displacement of indoor microform model measuring equipment according to claim 1, wherein the top view projections of the horizontal base point, the vertical base point, the adjusting device and the sensing device are in the same Cartesian two-dimensional coordinate system; the center point and the horizontal base point of the adjusting device and the sensing device are on the X axis, with the center of the sensing device as the circle point; the coordinates of the horizontal base point are (L4, 0), and the coordinates of the vertical base point are (0, L0).

3. The device for real-time monitoring and correcting the displacement of indoor microform model measuring equipment according to claim 1, wherein the truss is a frame structure, and the top center is vertically connected with a vertical truss downward.

4. The device for real-time monitoring and correcting the displacement of indoor microform model measuring equipment according to claim 1, wherein the measuring equipment and the sensing device are both installed on the vertical truss.

5. The device for real-time monitoring and correcting the displacement of indoor microform model measuring equipment according to claim 1, wherein the adjusting device comprises a steel square frame fixedly installed at the bottom of the vertical truss; the upper part of the two adjacent bottom edges of the square frame are respectively provided with guide rails arranged along the length thereof, and each bottom edge is provided with an electric push rod whose bottom is clamped on the guide rail; the two electric push rods are arranged in a cross, and the end shaft heads of the two electric push rods are fixedly connected to a collar; the collar is sleeved on an upwardly extending casing of the measuring equipment, and there is a gap between the collar and the casing, which can ensure that the measuring equipment can move up and down freely; each electric push rod is equipped with an electromagnetic chuck in contact with the bottom edge; the electromagnetic chuck fixes the electric push rod on the bottom edge when it is energized; when the electric push rod is required to slide on the bottom edge, the electromagnetic chuck is deenergized;
one of the electric push rods is equipped with a micro stepping motor that has an angle with the push rod on the shaft head closed to the end; the end of the output shaft of the micro stepping motor is equipped with a gear; the casing is provided with a rack meshed with the gear; when the micro stepping motor works, the gear rotates, and the casing and the measuring equipment move up and down through the action of the rack meshed with the gear.

6. The device for real-time monitoring and correcting the displacement of indoor microform model measuring equipment according to claim 5, wherein the electric push rod, the electromagnetic chuck and the micro stepping motor are all controlled by the controller.

7. The device for real-time monitoring and correcting the displacement of indoor microform model measuring equipment according to claim 1, wherein the sensing device is a laser displacement sensor.

8. The device for real-time monitoring and correcting the displacement of indoor microform model measuring equipment according to claim 1, wherein the controller is a PLC or a single-chip microcomputer or a computer.

9. A real-time monitoring and correcting method using the device for real-time monitoring and correcting the displacement of indoor microform model measuring equipment, comprising the following steps:
1) selecting a horizontal base point and a vertical base point with the same position; the top view projections of the horizontal base point, the vertical base point, the adjusting device and the sensing device are in the same Cartesian two-dimensional coordinate system; the center point and the horizontal base point of the adjusting device and the sensing device are on the X axis, with the center of the sensing device as the circle point; the coordinates of the horizontal base point are (L4, 0), and the coordinates of the vertical base point are (0, L0);
2) fixing the sensing device, the adjusting device and the measuring equipment on the vertical truss;
3) the sensing device measures its distance from the horizontal base point and the vertical base point by emitting a laser beam to the horizontal base point and the vertical base point;
4) setting the distance between the measuring equipment and the horizontal base point and the vertical base point unchanged, and the error is less than 0.01 mm;
5) automatic adjustment; if the measuring equipment has a displacement greater than or equal to 0.01 mm due to changes in the external environment, the sensing device will sense in real time and convert the displacement signal into an electrical signal and transmit it to the controller, and the controller controls the adjusting device to make corresponding adjustments to restore the measuring equipment to the standard position.
